(19) United States
(12) Patent Application Publication
(10) Pub. No.: US 2024/0234094 A9
(43) Pub. Date: Jul. 11, 2024

(54) PLASMA CONTROL DEVICE AND PLASMA CONTROL METHOD

(71) Applicant: SAMSUNG ELECTRONICS CO., LTD., Suwon-si (KR)

(72) Inventors: Changho KIM, Suwon-si (KR); Hyeongmo KANG, Suwon-si (KR); Illsang KO, Suwon-si (KR); Dooyoung GWAK, Suwon-si (KR); Kyungsun KIM, Suwon-si (KR); Namkyun KIM, Suwon-si (KR); Yirop KIM, Suwon-si (KR); Jihwan KIM, Suwon-si (KR); Seungbo SHIM, Suwon-si (KR); Minyoung HUR, Suwon-si (KR)

(73) Assignee: SAMSUNG ELECTRONICS CO., LTD., Suwon-si (KR)

(21) Appl. No.: 18/232,123

(22) Filed: Aug. 9, 2023

(30) Foreign Application Priority Data
Oct. 25, 2022 (KR) 10-2022-0138621

(51) Int. Cl. H01J 37/32

(52) U.S. Cl. CPC H01J 37/32183; H01J 37/32128; H01J 37/32165; H01J 37/3244; H01J 2237/334

(57) ABSTRACT

Provided is a plasma control method including applying gas to a chamber having a wafer loaded therein, generating plasma by applying both radio frequency (RF) power associated with a first voltage at a first frequency and a second voltage at a second frequency that is lower than the first frequency to the chamber for a first time, cutting off the RF power after the first time elapses, continuously applying the second voltage of the second frequency to the chamber for a second time, cutting off the second voltage after the second time elapses, continuously maintaining an off state of the RF power and an off state of the voltage for a third time, and performing an etching process on the wafer by using the plasma formed by the RF power and the second voltage after the third time elapses, wherein the RF power is a sine wave, and the second voltage is a square wave of a periodic pulse form.

### CROSS-REFERENCE TO RELATED APPLICATION

This application is based on and claims priority under 35 U.S.C. § 119 to Korean Patent Application No. 10-2022-0138621, filed on Oct. 25, 2022, in the Korean Intellectual Property Office, the disclosure of which is incorporated by reference herein in its entirety.

### BACKGROUND

Embodiments relate to a plasma control device and a plasma control method.

In general, a series of processes, such as deposition, etching, and cleaning, may be performed to manufacture a semiconductor device. These processes may be performed by a deposition, etching, or cleaning device including a process chamber. Meanwhile, a plasma technique, such as capacitively coupled plasma (CCP), inductively coupled plasma (ICP), or a combination of CCP and ICP, is employed to improve selectivity and minimize damage of layer quality of a wafer. The plasma technique includes a direct plasma technique of directly generating plasma inside a process chamber that is a wafer processing space and a remote plasma technique of generating plasma outside a process chamber and supplying the plasma to the process chamber.

### SUMMARY

Embodiments provide a plasma control device and a plasma control method capable of alleviating charge accumulation in a high aspect ratio pattern by plasma.

In addition, the problems to be solved by the technical idea are not limited to the problem mentioned above, and the other problems could be clearly understood by those of ordinary skill in the art from the description below.

Provided herein is a plasma control method including: applying gas to a chamber, wherein a wafer has been loaded into the chamber; generating a plasma by applying both radio frequency (RF) power of a first voltage at a first frequency and a second voltage at a second frequency that is lower than the first frequency to the chamber until a first time is reached; cutting off the RF power after the first is reached; continuously applying the second voltage of the second frequency to the chamber until a second time is reached; cutting off the second voltage after the second time is reached; maintaining an off state of the RF power and of the second voltage after the second time is reached; and commencing, when a third time is reached, an etching process on the wafer by using the plasma formed by the RF power and the second voltage, wherein the RF power is a sine wave, and the second voltage is a square wave of a periodic pulse form.

Also provided herein is a plasma control method including: applying radio frequency (RF) power of first voltage at a first frequency and a second voltage at a second frequency that is lower than the first frequency to a chamber, wherein a wafer has been loaded into the chamber; generating a plasma in the chamber by using the RF power and the second voltage; and processing the wafer by using the plasma, wherein the RF power is a sine wave, the second voltage is a square wave of a periodic pulse form, the first frequency is about 30 MHz to about 50 MHz, and the second frequency is about 300 kHz to about 500 kHz.

Also provided herein is a plasma control device including: a chamber configured to hold a wafer, the chamber providing a space for generating plasma; a radio frequency (RF) power source configured to generate a first voltage to be applied to the chamber, the first voltage corresponding to an RF power; a voltage source configured to generate a second voltage to be applied to the chamber; a controller configured to control supply times, frequencies, and voltage values of the RF power and the second voltage; and a matcher between the RF power source and the chamber, wherein the RF power source includes a first source connected to a first electrode at a lower part of the chamber and configured to apply RF power of a first frequency, the first frequency is higher than a second frequency, the voltage source is connected to the first electrode and further configured to apply to the chamber the second voltage of the second frequency, and the matcher is configured to present an impedance match to the RF power source.

### BRIEF DESCRIPTION OF THE DRAWINGS

Embodiments will be more clearly understood from the following detailed description taken in conjunction with the accompanying drawings in which:

FIG. 1 is a conceptual diagram schematically illustrating a plasma control device according to an exemplary embodiment;

FIG. 2 is a flowchart illustrating a plasma control method according to an exemplary embodiment;

FIG. 3 is a flowchart illustrating a plasma control method according to an exemplary embodiment;

FIGS. 4 to 8 are graphs illustrating frequency waveforms of radio frequency (RF) power and a voltage applied through RF power sources in the plasma control device of FIG. 1;

FIG. 9 is a graph illustrating stage-based density changes of main species of plasma, according to an exemplary embodiment;

FIG. 10A illustrates a plasma potential in a chamber in State 3 of FIG. 9;

FIG. 10B illustrates a distribution of the flux of negative ions in the chamber in State 3 of FIG. 9;

FIG. 11 is a graph illustrating stage-based spatial distributions of a plasma potential in a chamber in a vertical direction from an electrode, according to an exemplary embodiment; and

FIG. 12 is a magnified graph of a portion of the graph of FIG. 11.

### DETAILED DESCRIPTION OF THE EMBODIMENTS

Hereinafter, embodiments are described in detail with reference to the accompanying drawings. Like reference numerals in the drawings denote like elements, and thus their repetitive description is omitted.

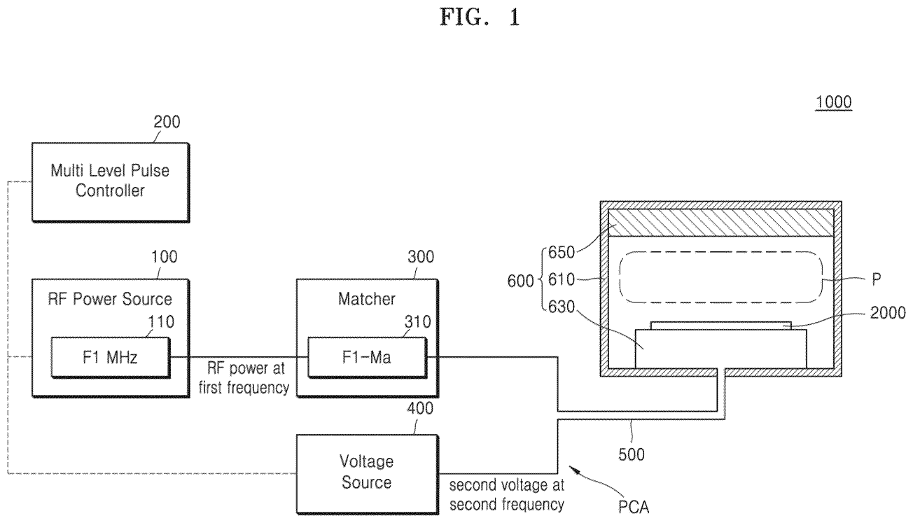

FIG. 1 is a conceptual diagram schematically illustrating a plasma control device 1000 according to an embodiment.

Referring to FIG. 1, the plasma control device 1000 according to the present embodiment may include a radio frequency (RF) power source 100, a multi-level pulse controller 200, a matcher 300, a voltage source 400, a transmission line 500, and a chamber 600. The plasma control device 1000 may be a plasma control apparatus (PCA). Transmission line 500 of FIG. 1, in some embodiments, indicates a first transmission line from the matcher 300 to the chamber 600 and a second transmission line from the voltage source 400 to the chamber 600. The transmission lines may be coupled to a bottom electrode of the chamber 600 by conventional circuit or transmission line coupling devices or connectors.

The plasma control device 1000 may be configured to generate plasma. The plasma control device 1000 may include a capacitively coupled plasma (CCP) source, an inductively coupled plasma (ICP) source, a microwave plasma source, a remote plasma source, or the like.

The RF power source 100 may generate RF power and supply the RF power to the chamber 600. In addition, the voltage source 400 may generate a voltage and supply the voltage to the chamber 600. The RF power source 100 may generate and output RF power of various frequencies. For example, the RF power source 100 may include at least one RF source, i.e., a first source 110. Herein, the first source 110 may generate RF power having a first frequency F1 in a range of several MHz to tens of MHz. The voltage source 400 may generate a voltage having a second frequency in a range of tens of kHz to hundreds of kHz. In addition, the RF power source 100 and the voltage source 400 may generate and output power of hundreds to tens of thousands watts (W).

In the plasma control device 1000, although it is illustrated that the RF power source 100 includes one source, i.e., the first source 110, the RF power source 100 may include two or more sources. In addition, a frequency range and power of RF power generated by a source are not limited to the frequency range and power described above. For example, according to an embodiment, the at least one RF source included in the RF power source 100 may generate RF power having a frequency that is lower than or equal to tens of kHz or higher than or equal to hundreds of MHz. In addition, the at least one RF source included in the RF power source 100 may generate RF power having power lower than or equal to hundreds of watts or higher than or equal to thousands of watts.

As a reference, in the plasma control device 1000, the RF power source 100 may correspond to a power source configured to supply power to the chamber 600. In addition, the chamber 600 may be considered as a kind of load, which receives power from the RF power source 100.

In the plasma control device 1000, the RF power source 100 may include at least one RF source to generate RF power of various frequencies and supply the RF power to the chamber 600. By using the RF power source 100, the ion energy and plasma density of the chamber 600 may be independently controlled. For example, RF power of a high frequency, which is provided from the first source 110, may be used to generate plasma P, and a voltage of a low frequency, which is provided from the voltage source 400, may be used to supply energy to ions and generate the plasma P together with the first source 110. Thus, the ion energy and plasma density in the chamber 600 are controlled.

In addition, according to an embodiment, the voltage may be applied in a periodic pulse form having a square wave form and reduce charges accumulated on a pattern in a wafer. In addition, according to an embodiment, the RF power source 100 may further include a second source (not shown in FIG. 1). The second source may reinforce RF power from the first source 110.

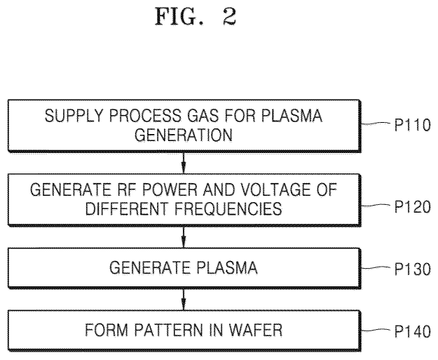

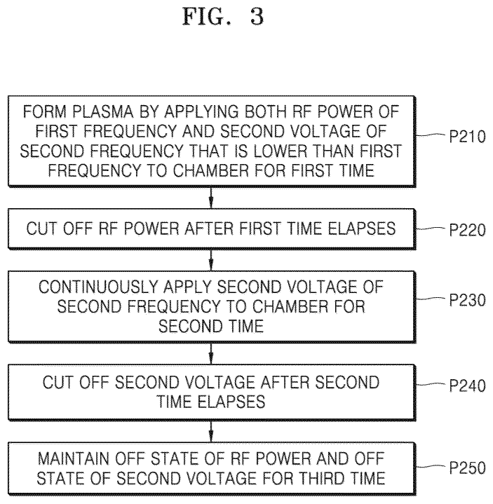

The multi-level pulse controller 200 may control bursts of RF power and voltage waveforms of various frequencies, which are generated by the RF power source 100 and the voltage source 400, respectively. For example, the multi-level pulse controller 200 may control a frequency, a supply time, a pulse level, a power, and the like of RF power. In embodiments, the multi-level pulse controller 200 may apply RF power from the RF power source 100 and a voltage from the voltage source 400 to the chamber 600 by combining voltage waveforms and bursts of RF power of various frequencies from the voltage source 400 and the RF power source 100, respectively. In embodiments, the multi-level pulse controller 200 may establish an RF power supply scheme of first to third stages to reduce charges accumulated on a pattern in a wafer. Stages of control over time performed by the multi-level pulse controller 200 are described below with reference to FIGS. 2 and 3.

The matcher 300 may control an impedance so that RF power from the RF power source 100 is maximally delivered to the chamber 600. For example, the matcher 300 may maximize RF power delivery by controlling an impedance to satisfy a complex conjugate condition based on a maximum power delivery theory. In other words, the matcher 300 may control an impedance for the RF power source 100 to operate in an environment of 50Ω so that reflected power is minimized, thereby maximally delivering RF power from the RF power source 100 to the chamber 600. For example, the matcher may adjust an input impedance as viewed by the RF power source 100 looking toward the chamber 600 so that maximum power transfer is substantially achieved from the RF power source 100 to the chamber 600. Thus power output by the RF power source 100 and then reflected back to the RF power source 100 is minimized.

The matcher 300 may include a first sub-matcher 310 in correspondence to a frequency of RF power. For example, the matcher 300 may include the first sub-matcher 310, which corresponds to the first frequency F1 of the first source 110. The first sub-matcher 310 may control an impedance so that RF power of a corresponding frequency is maximally delivered. In an embodiment, a sub-matcher corresponding to the second frequency of the voltage may not be included. The voltage may not be applied to the matcher 300 but applied to the chamber 600.

The voltage source 400 may generate a voltage for control of ion energy. The voltage source 400 may amplify the voltage for control of ion energy. In addition, the voltage source 400 may convert the voltage for control of ion energy into a bias direct current (DC) voltage. In addition, the voltage source 400 may include a DC modulator.

The transmission line 500 may be between the matcher 300 and the chamber 600 to deliver RF power to the chamber 600. Although not particularly shown in FIG. 1, the transmission line 500 may also be between the RF power source 100 and the matcher 300.

The transmission line 500 may be implemented by, for example, a coaxial cable, an RF strap, an RF rod, or the like. The coaxial cable may include a central conductor, an outer conductor, an insulator, and a sheath. The coaxial cable may have a structure in which the central conductor is coaxial with the outer conductor. In general, because the coaxial cable attenuates a signal a little up to a high frequency, the coaxial cable is suitable for broadband transmission, and in addition, leakage may be controlled to be small due to the presence of the outer conductor. Accordingly, the coaxial cable may be mainly used as a transmission cable for a high frequency. For example, the coaxial cable may effectively deliver RF power having a frequency in a range of several MHz to tens of MHz without leakage. The coaxial cable may have two types of characteristic impedances of 50Ω and 75Ω.

The RF strap may include a strap conductor, a ground housing, and an insulator. The strap conductor may have a shape like a strap extending in one direction. The ground housing may have a circular tubular shape surrounding the strap conductor with a certain distance between the ground housing and the strap conductor. The ground housing may protect the strap conductor from RF radiation. The insulator may fill between the strap conductor and the ground housing. The RF rod may include a rod conductor instead of the strap conductor of the RF strap. The rod conductor of the RF rod may have a circular column shape extending in one direction. The RF strap or the RF rod may deliver RF power having a frequency in a range of, for example, several MHz to tens of MHz.

An impedance characteristic of the transmission line 500 may depend on the physical characteristics of an implemented coaxial cable, RF strap, RF rod, or the like. Alternatively, when the transmission line 500 is implemented by an RF strap or an RF rod, the impedance characteristic of the transmission line 500 may be changed by changing a length of a strap conductor or a rod conductor, a size of a space of a ground housing, or a dielectric constant and/or permeability of an insulator.

The chamber 600 may include a chamber body 610, an electrostatic chuck 630, and a shower head 650. The chamber 600 is a chamber for a plasma process and, the plasma P may be generated inside the chamber 600. The chamber 600 may be a CCP chamber, an ICP chamber, or a CCP and ICP combined chamber. The chamber 600 is not limited to the chambers described above. The plasma control device 1000 may be distinguished by a CCP scheme, an ICP scheme, and a CCP and ICP mixed scheme according to a type of a plasma chamber and a type of RF power applied to the plasma chamber. The plasma control device 1000 according to the present embodiment may use the CCP or ICP scheme. Alternatively, the plasma control device 1000 according to the present embodiment may be implemented by the CCP and ICP mixed scheme.

The chamber body 610 limits a reaction space in which the plasma P is formed, so that the reaction space is sealed from the outside. The chamber body 610 may be generally formed of a metal material and maintain a ground state to block noise from the outside during a plasma process. Although not shown in FIG. 1, a gas inlet, a gas outlet, a view-port, and the like may be formed in the chamber body 610. Process gas necessary for a plasma process may be supplied through the gas inlet. Herein, the process gas may indicate all types of gases, such as source gas, reaction gas, and purge gas, required in a plasma process. After a plasma process, gases inside the chamber 600 may be discharged to the outside through the gas outlet. In addition, internal pressure of the chamber 600 may be adjusted through the gas outlet. One or more view-ports may be formed in the chamber body 610, and the inside of the chamber 600 may be monitored through the view-port.

The electrostatic chuck 630 may be at a lower part inside the chamber 600. A wafer 2000, which is a target of a plasma process, may be fixed on an upper surface of the electrostatic chuck 630. The electrostatic chuck 630 may fix the wafer 2000 by an electrostatic force. In addition, the electrostatic chuck 630 may include a bottom electrode for a plasma process. The electrostatic chuck 630 may be connected to the RF power source 100 via the transmission line 500. Accordingly, RF power from the RF power source 100 may be applied to the inside of the chamber 600 via the electrostatic chuck 630.

The shower head 650 may be at an upper part inside the chamber 600. The shower head 650 may spray, through a plurality of spray holes, process gas supplied through the gas inlet. The shower head 650 may include a top electrode. The shower head 650 may be connected to, for example, the ground in a plasma process.

Although not shown in FIG. 1, the plasma control device 1000 may include at least one RF sensor. The at least one RF sensor may be provided to an output end of the RF power source 100, an input end or an output end of the matcher 300, or the like. The at least one RF sensor is configured to measure RF power to be delivered to the chamber 600. In general the chamber 600 is characterized by an impedance. By monitoring a state of the chamber 600 through the at least one RF sensor, RF power delivery to the chamber 600 may be effectively managed and controlled, and accordingly, a plasma process may be precisely performed.

Although etching has been mainly described above, the plasma control device 1000 according to the present embodiment may be used for a deposition process or a cleaning process. Therefore, the plasma control device 1000 according to the present embodiment may uniformly perform deposition or cleaning on the wafer 2000, which is a target of a plasma process, through plasma distribution uniformization. Plasma distribution uniformization means making a density of a plasma distribution more uniform over the wafer 2000. Also, the plasma control device 1000 may be used for not only an etching process but also a deposition process or a cleaning process.

FIG. 2 is a flowchart illustrating a plasma control method according to an embodiment. FIG. 2 is described with reference to FIG. 1. Not all details of FIG. 1 are repeated in the discussion of FIG. 2.

Referring to FIG. 2, in a plasma control method in the plasma control device 1000 (hereinafter, simply “plasma control method”), process gas for plasma generation may be supplied to the chamber 600, in operation P110. Herein, the process gas may indicate all types of gases, such as source gas, reaction gas, and purge gas, required in a plasma process. The process gas may be provided from a process gas source to the shower head 650 of the chamber 600 through a gas supply pipe and the gas inlet and supplied to the inside of the chamber 600 through the plurality of spray holes of the shower head 650.

Next, in operation P120, the RF power source 100 and the voltage source 400 may generate RF power and voltages of different frequencies, respectively. The outputs of the RF power source 100 and the voltage source 400 are applied to the chamber 600 as shown schematically in FIG. 1. More particularly, the RF power source 100 may include the first source 110. The first source 110 may generate a first voltage of a first frequency associated with RF power and referred to below as RF power, and the voltage source 400 may generate a second voltage of a second frequency. Each of the first source 110 and the voltage source 400 may be connected to the bottom electrode (not shown), and the RF power and the second voltage may be applied to the chamber 600 via the bottom electrode.

Frequency magnitudes, frequency waveforms, power levels, and the like of the RF power for control of plasma density and the second voltage (for control of ion energy and for plasma generation) are the same as described for the plasma control device 1000 of FIG. 1. In general the voltage source 400 provides the second voltage for both generating the plasma and for controlling ion energy. Accordingly, in the plasma control method according to the present embodiment, a frequency associated with the RF power may be greater than a frequency associated with the voltage.

Next, in operation P130, the RF power and the voltage for control of ion energy may be applied to the chamber 600 to generate plasma inside the chamber 600. The RF power may be applied to the chamber 600 after an impedance of the RF power is controlled by the first sub-matcher 310 of the matcher 300, which corresponds to the RF power. Although FIG. 2 shows that the generation of the RF power and the second voltage are separated from the application of the RF power for control of plasma density and the second voltage to the chamber 600, the generation and the application may be performed substantially almost at the same time. In addition, according to an embodiment, the supply of the process gas to the chamber 600 may also be simultaneously performed with the application of the RF power for control of plasma density and the second voltage, or according to a type of the process gas, the supply of the process gas may be later than the application of the RF power and the voltage.

Next, in operation P140, a pattern may be formed in a wafer by using the generated plasma. As described with reference to FIG. 1, the pattern may be formed in the wafer by performing any one of an etching process, a cleaning process, a deposition process, a plasma process, and the like.

In addition, although not shown in the flowchart of FIG. 2, an operation of electrostatically fixing, i.e., chucking, the wafer 2000 on the electrostatic chuck 630 when a plasma process starts and an operation of releasing, i.e., dechucking, the electrostatic fixing of the wafer 2000 after the plasma process ends may be performed. These chucking and dechucking operations are basically performed in a plasma process and thus may also be included in plasma control methods according to some embodiments.

In the plasma control method according to the present embodiment, the RF power for control of plasma density or the voltage for control of ion energy may be applied in a continuous wave form or a pulse wave form. In addition, the RF power and the voltage may be applied to the chamber 600 in a form that an on state of the RF power is included in an on state of the voltage. As a result, in the plasma control method according to the present embodiment, RF power and a voltage of RF power sources (e.g., the first source 110 and the voltage source 400) may be applied to the chamber 600 with different frequencies and waveforms (e.g., a sine wave or a square wave), thereby improving plasma dispersion inside the chamber 600 and solving phase sensitivity due to the use of a same frequency.

FIG. 3 is a flowchart illustrating a plasma control method according to an embodiment. The flowchart of FIG. 3 indicates a method for operation P120 of generating bursts of RF power of different frequencies and operation P130 of generating plasma. Herein, a description is made with reference to FIG. 1 together, and a description already made with reference to FIGS. 1 and 2 is simply repeated or omitted.

Referring to FIG. 3, in the plasma control method, in operation P210, plasma may be generated by applying both RF power of the first frequency F1 and a voltage of a second frequency that is lower than the first frequency F1 to the chamber 600 for a first time. The first frequency F1 may be a high frequency, and the second frequency may be a low frequency. Operation P210 may be referred to as a main process. The multi-level pulse controller 200 may adjust the first time. For example, the multi-level pulse controller 200 may set the first time to 50 μs when the multi-level pulse controller 200 operates at 10 kHz.

The plasma control device 1000 may perform most processes required to form a pattern in a wafer, by using the generated plasma. The RF power supplied to the chamber 600 may be RF power of which an impedance is controlled by the matcher 300. In addition, the voltage may be a bias DC voltage amplified by the voltage source 400.

Next, in operation P220, the RF power may be cut off after the first time elapses. In operation P230, the voltage of the second frequency from voltage source 400 may be continuously applied to the chamber 600 for a second time after cutting off the RF power. Operations P220 and P230 may be referred to as a residual process. In the residual process, jobs, which have not been processed in the main process, may be additionally performed by using the voltage from voltage source 400.

The second frequency of the voltage supplied to the chamber 600 for the second time may be controlled by the multi-level pulse controller 200 to be lower or higher than the second frequency of the voltage supplied to the chamber 600 for the first time.

A difference between the second frequency of the second voltage applied for the second time and the second frequency of the second voltage applied for the first time may be within a range of about 1 kHz to about 500 kHz. In addition, the second voltage applied for the first time and the second voltage applied for the second time may be either a bipolar voltage or a unipolar voltage.

Alternatively, the second frequency of the second voltage supplied to the chamber 600 for the second time may be controlled by the multi-level pulse controller 200 to be the same as the second frequency of the second voltage supplied to the chamber 600 for the first time.

The second voltage may be continuously applied to the chamber 600 for the first time and the second time. In exemplary embodiments, the RF power may be supplied to the chamber 600 for the first time, whereas the second voltage from the voltage source 400 may be supplied to the chamber 600 for the first time and the second time. That is, a supply time of the second voltage may be longer than a supply time of the RF power.

The multi-level pulse controller 200 may control the second time to sufficiently decrease a electron density of plasma formed inside the chamber 600. The multi-level pulse controller 200 may control the second time to be at least 10 μs (microseconds). The second time may be shorter than the first time. However, embodiments are not limited thereto.

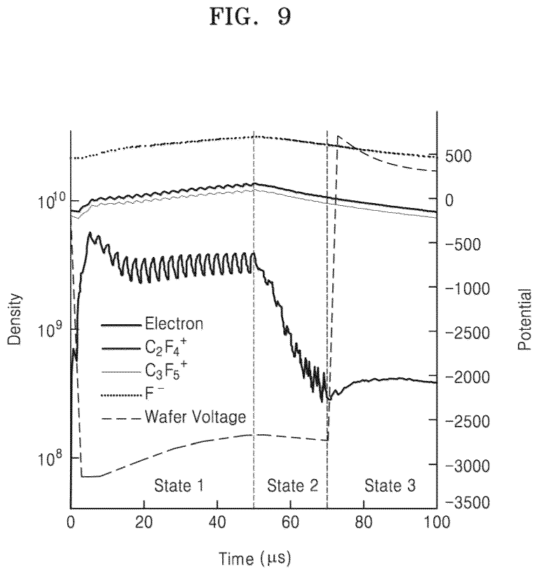

By supplying the second voltage in an off state of the RF power, the density of electrons in plasma formed inside the chamber 600 tends to decrease. By doing this, in operations P240 and P250 described below, an ion-ion plasma state may be formed inside the chamber 600. The ion-ion plasma state may indicate a state in which a difference between an electron density and an ion density is very large because electrons in plasma are depleted. A detailed description of the ion-ion plasma state is made with reference to FIG. 9.

Next, in operation P240, the second voltage is cut off after the second time elapses, and in operation P250, the off state of the RF power and an off state of the second voltage may be maintained for a third time. Due to the decrease in the electron density in operations P220 and P230, the plasma inside the chamber 600 may approach the ion-ion plasma state in operations P240 and P250. For example, in ion-ion plasma formed inside the chamber 600, a difference between the electron density and the ion density may be about 100 times.

In embodiments, the multi-level pulse controller 200 may control the third time so that negative ions of the plasma formed inside the chamber 600 sufficiently move to the pattern in the wafer inside the chamber 600. In embodiments, a duration of the off state of the RF power and the off state of the voltage may be at least 20 μs. In embodiments, the duration of the off state of the RF power and the off state of the second voltage may be at least 25 μs. In embodiments, a duration of the off state of the RF power and the off state of the second voltage may be at least 30 μs.

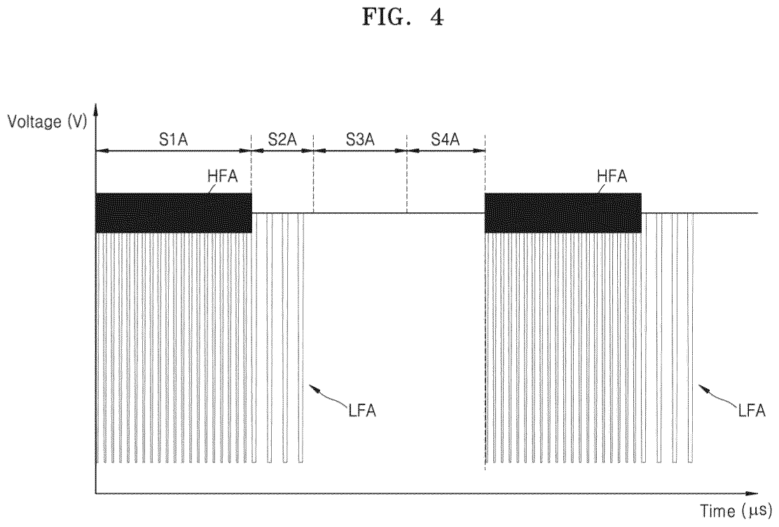

FIGS. 4 to 8 are graphs illustrating frequency waveforms of RF power and a second voltage applied through RF power sources in the plasma control device 1000 of FIG. 1. In the graphs of FIGS. 4 to 8, the horizontal axes indicate time (unit is μs), and the vertical axes indicate voltage (unit is V). Each graph shows an RF power application form of two periods, but an RF power application form of one period is described below.

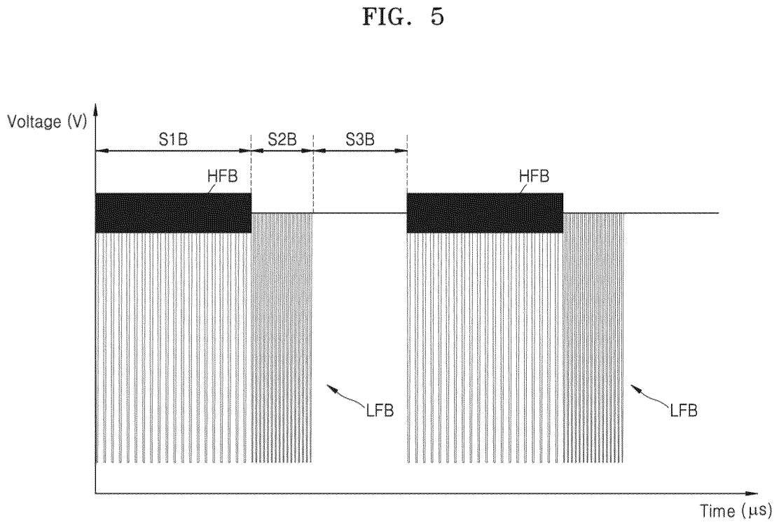

Referring to FIGS. 4 and 5, the plasma control device 1000 according to an embodiment may applies both RF power HFA or HFB and a second voltage LFA or LFB (second voltages) to the chamber 600 for a first time S1A or SIB, cut off the RF power HFA or HFB and continuously apply the voltage LFA or LFB to the chamber 600 for a second time S2A or S2B, and cut off both the RF power HFA or HFB and the voltage LFA or LFB for a third time S3A or S3B. Herein, each of the RF power HFA and the RF power HFB is a sine wave having a voltage in a range of about 1000 V to about −1000 V. Each of the voltages LFA and LFB is a square wave of a periodic pulse form in a range of about 0 V to about −7000 V. However, the voltages of the RF power and the voltage source 400 may be higher or lower than the values shown in the graphs and are not limited to the voltage values shown in the graphs.

Referring to FIG. 4, a frequency of the voltage LFA is set to be higher for the second time S2A than for the first time S1A. In addition, referring to FIG. 5, a frequency of the voltage LFB is set to be lower for the second time S2B than for the first time S1B. As described above, the frequency of the voltage LFA or LFB applied for the first time S1A or S1B may be set different from the frequency of the voltage LFA or LFB applied for the second time S2A or S2B.

During a fourth time, an etching process on the wafer is performed by using the plasma formed by the RF power and the second voltage after the third time elapses. See the interval S4A in FIG. 4.

Thus, as seen in FIG. 4, embodiments include generating a plasma by applying both radio frequency (RF) power of a first voltage at a first frequency and a second voltage at a second frequency that is lower than the first frequency to the chamber until a first time is reached (see S1A of FIG. 4). Embodiments include cutting off the RF power after the first is reached (see the end of HFA in FIG. 4). Embodiments include continuously applying the second voltage of the second frequency to the chamber until a second time is reached (see S2A in FIG. 4) and cutting off the second voltage after the second time is reached (see the cessation of LFA at the end of S2A). Embodiments include maintaining an off state of the RF power and of the second voltage after the second time is reached (see the end of S2A in FIG. 4), and commencing, when a third time is reached, an etching process on the wafer by using the plasma formed by the RF power and the second voltage (see the end of S3A and the beginning of S4A in FIG. 4). In some embodiments, the RF power is associated with the first voltage as a sine wave, and the second voltage is a square wave of a periodic pulse form.

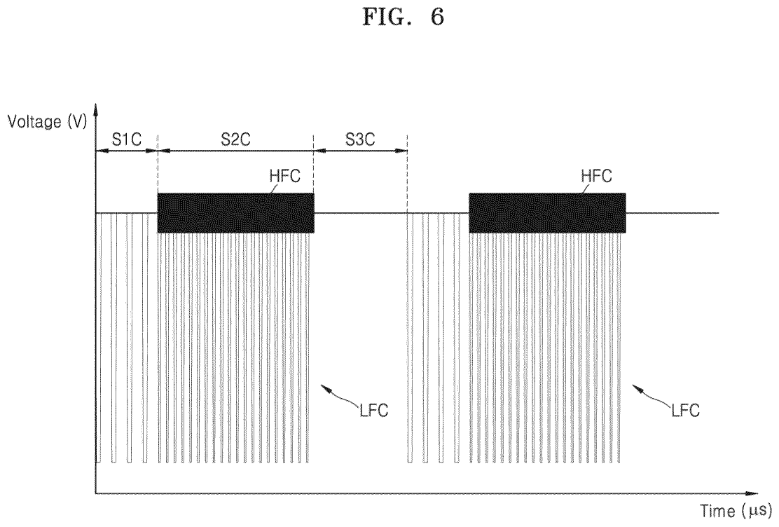

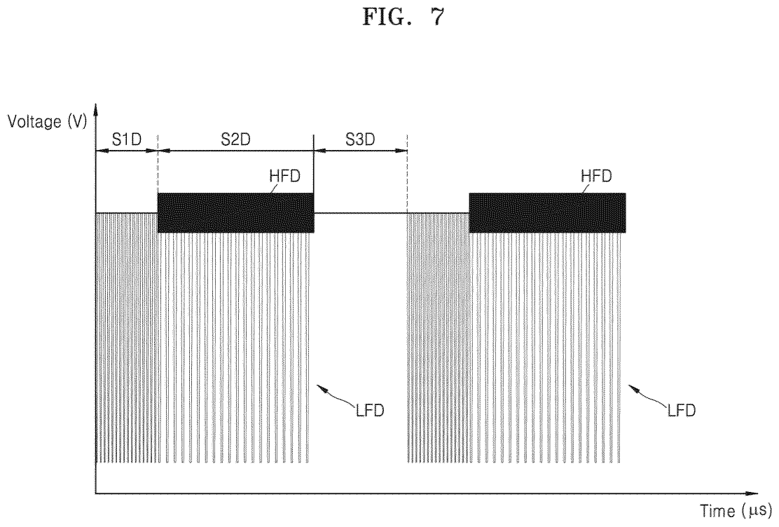

Referring to FIGS. 6 and 7, the plasma control device 1000 according to an embodiment may apply a voltage LFC or LFD (second voltages) to the chamber 600 for a first time S1C or S1D, apply both RF power HFC or HFD and the voltage LFC or LFD to the chamber 600 for a second time S2C or S2D, and cut off both the RF power HFC or HFD and the voltage LFC or LFD for a third time S3C or S3D. Herein, each of the RF power HFC and the RF power HFD is a sine wave having a voltage in a range of about 1000 V to about −1000 V. Each of the voltages LFC and LFD is a square wave of a periodic pulse form in a range of about 0 V to about −7000 V. However, the voltages of the RF power and the voltage source 400 may be higher or lower than the values shown in the graphs and are not limited to the voltage values shown in the graphs. The time interval devoted to etching is not shown in FIGS. 6-8.

Referring to FIG. 6, a frequency of the voltage LFC is set to be higher for the second time S2C than for the first time SIC. In addition, referring to FIG. 7, a frequency of the voltage LFD is set to be lower for the second time S2D than for the first time S1D. As described above, the frequency of the voltage LFC or LFD applied for the first time S1C or SID may be set different from the frequency of the voltage LFC or LFD applied for the second time S2C or S2D.

Referring to FIGS. 4 to 7, the plasma control device 1000 according to an embodiment may apply the voltages LFA, LFB, LFC, and LFD in a unipolar form.

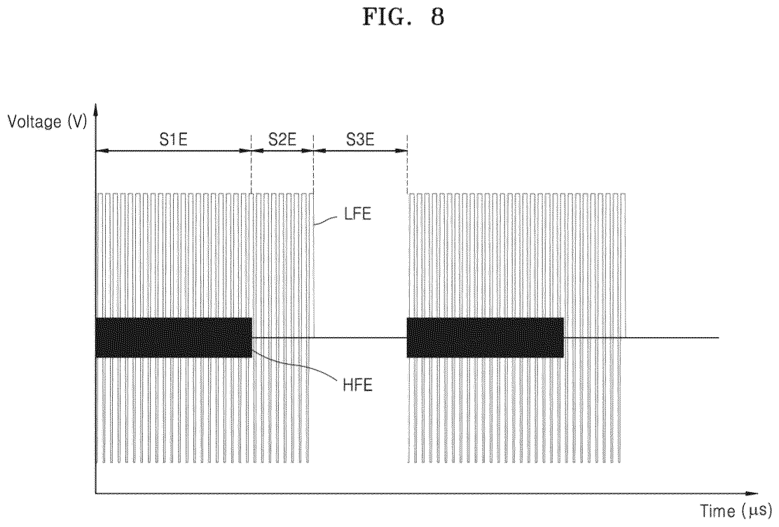

Referring to FIG. 8, the plasma control device 1000 according to an embodiment may apply both RF power HFE and a voltage LFE to the chamber 600 for a first time S1E, cut off the RF power HFE and continuously apply the voltage LFE to the chamber 600 for a second time S2E, and cut off both the RF power HFE and the voltage LFE for a third time S3E. The plasma control device 1000 may set the same frequency of the voltage LFE to be applied for the first time S1E and for the second time S2E. In addition, the plasma control device 1000 may apply the voltage LFE in a bipolar form.

FIG. 9 is a graph illustrating stage-based density changes of main species of plasma, according to an embodiment.

Referring to FIG. 9, the horizontal axis of the graph indicates time (unit is μs), the left vertical axis of the graph indicates density (arbitrary unit), and the right vertical axis of the graph indicates potential (arbitrary unit). State 1 indicates a state in which both RF power and a voltage are applied, State 2 indicates a state in which the RF power is cut off, and the voltage is applied, and State 3 indicates a state in which both the RF power and the voltage are cut off.

Among the main species of plasma, positive ions (C₂F₄⁺ and C₃F₅⁺) and negative ions (F⁻) increase a little in State 1 and decrease a little in State 2 and State 3 but are generally maintained. In addition, among the main species of plasma, electrons converge to a particular value due to application of RF power in State 1 but sharply decrease in State 2. Accordingly, the ion-ion plasma state in which a difference between an electron density and an ion density is very large is formed in State 3.

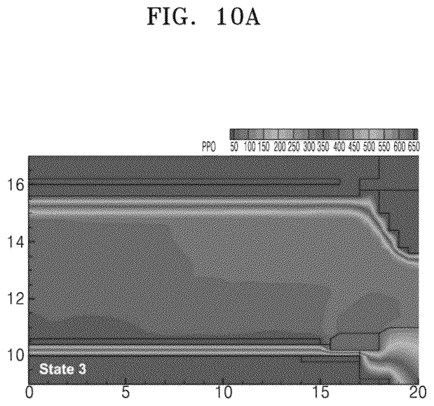

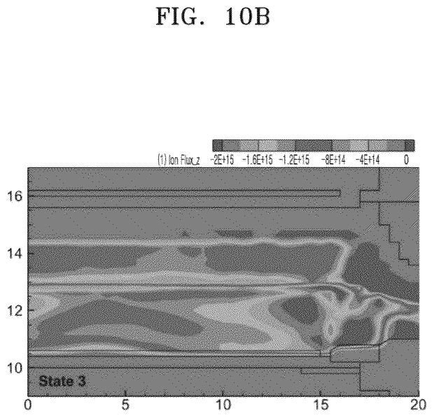

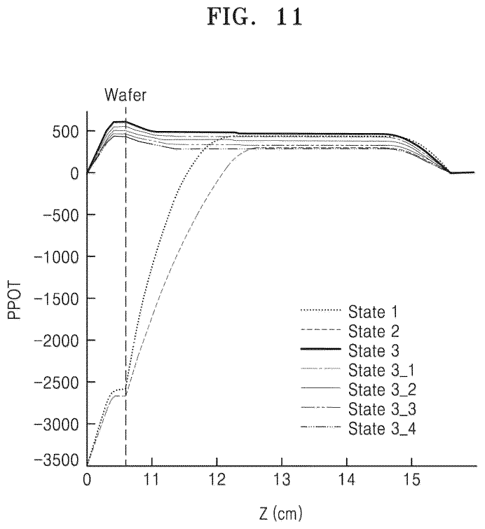

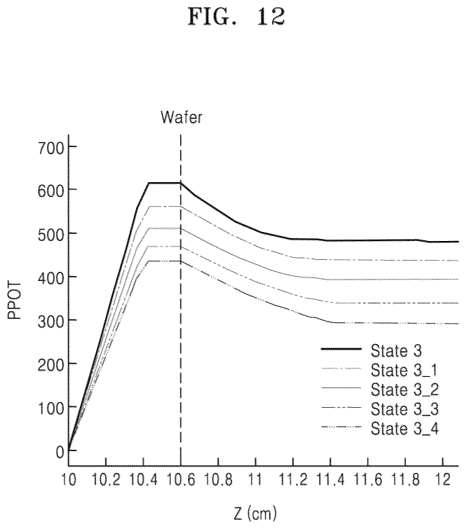

FIG. 10A illustrates a plasma potential in a chamber in State 3 of FIG. 9. FIG. 10B illustrates a distribution of the flux of negative ions in the chamber in State 3 of FIG. 9. FIG. 11 is a graph illustrating stage-based spatial distributions of a plasma potential in a chamber in a vertical direction from an electrode, according to an embodiment. FIG. 12 is a magnified graph of a portion of the graph of FIG. 11. In FIGS. 11 and 12, the horizontal axis of each graph indicates a first directional height (unit is cm) vertical to a wafer, and the vertical axis of each graph indicates a plasma potential.

Referring to FIGS. 10A, 10B, 11, and 12, images show cross-sectional views of the chamber 600 cut in a first direction vertical to a wafer. In State 3, a plasma potential is relatively higher at a lower part of an internal space of the chamber 600 above the wafer than at a central part of the internal space of the chamber 600. In addition, in State 3, the flux of negative ions (e.g., F⁻) is higher at the lower part of the internal space of the chamber 600 above the wafer than at the central part or an upper part of the internal space of the chamber 600.

As described above, by applying both RF power and a second voltage (State 1), applying only the second voltage with the RF power cut off (State 2), and cutting off both the RF power and the second voltage (State 3), the ion-ion plasma state may be formed, and the flux of many negative ions may be formed at the lower part of the internal space of the chamber 600. By forming this state, positive charges accumulated on a pattern in a wafer may be reduced, and the pattern in the wafer may be uniformly etched.

Various changes in form and details may be made to the embodiments described above without departing from the spirit and scope of the following claims.

What is claimed is:

1. A plasma control method comprising:
applying gas to a chamber, wherein a wafer has been loaded into the chamber;
generating a plasma by applying both radio frequency (RF) power of a first voltage at a first frequency and a second voltage at a second frequency that is lower than the first frequency to the chamber until a first time is reached;
cutting off the RF power after the first is reached;
continuously applying the second voltage of the second frequency to the chamber until a second time is reached;
cutting off the second voltage after the second time is reached;
maintaining an off state of the RF power and of the second voltage after the second time is reached; and
commencing, when a third time is reached, an etching process on the wafer by using the plasma formed by the RF power and the second voltage,
wherein the RF power is a sine wave, and the second voltage is a square wave of a periodic pulse form.

2. The plasma control method of claim 1, wherein an impedance of the RF power is controlled by a matcher, and
the second voltage is a bias direct current voltage amplified by a voltage source.

3. The plasma control method of claim 1, wherein the second frequency of the second voltage applied for the second time is different from the second frequency of the second voltage applied for the first time.

4. The plasma control method of claim 3, wherein a difference between the second frequency of the second voltage applied for the first time and the second frequency of the second voltage applied for the second time is about 1 kHz to about 500 kHz.

5. The plasma control method of claim 1, wherein the second frequency of the second voltage applied for the second time is the same as the second frequency of the second voltage applied for the first time, and
the second voltage is continuously supplied for the first time and the second time.

6. The plasma control method of claim 1, wherein the second voltage applied for the first time and the second voltage applied for the second time are either a bipolar voltage or a unipolar voltage.

7. The plasma control method of claim 1, wherein the continuously maintaining the off state comprises continuously maintaining the off state of the RF power and the second voltage so that negative ions inside the chamber move to the wafer.

8. A plasma control method comprising:
applying radio frequency (RF) power of first voltage at a first frequency and a second voltage at a second frequency that is lower than the first frequency to a chamber, wherein a wafer has been loaded into the chamber;
generating a plasma in the chamber by using the RF power and the second voltage; and
processing the wafer by using the plasma,
wherein the RF power is a sine wave, the second voltage is a square wave of a periodic pulse form,
the first frequency is about 30 MHz to about 50 MHz, and
the second frequency is about 300 kHz to about 500 kHz.

9. The plasma control method of claim 8, wherein the applying the RF power and the second voltage comprises:
controlling an impedance of the RF power by using a matcher; and
amplifying the second voltage by using a voltage source.

10. The plasma control method of claim 8, wherein the applying the RF power and the second voltage comprises:
applying both the RF power and the second voltage; and
cutting off the RF power and continuously applying the second voltage to decrease an electron density inside the chamber.

11. The plasma control method of claim 9, further comprising, after the applying the RF power and the second voltage, cutting off both the RF power and the second voltage,
wherein, while the RF power and the second voltage are cut off, a plasma potential formed inside the chamber is higher at a lower part of the chamber than at a central part of the chamber.

12. The plasma control method of claim 8, wherein the second voltage is applied longer for at least 10 μs than the RF power.

13. The plasma control method of claim 8, wherein the generating the plasma in the chamber by using the RF power and the second voltage comprises generating an ion-ion plasma with reduced electrons as a time passes during the generating.

14. The plasma control method of claim 8, wherein the second voltage is produced by a voltage source coupled to the chamber, and an impedance of the chamber observed by the voltage source is not controlled by a matcher.

15. The plasma control method of claim 8, wherein, when the second voltage is in an on state, the RF power is applied in an on state.

16. A plasma control device comprising:
a chamber configured to hold a wafer, the chamber providing a space for generating plasma;
a radio frequency (RF) power source configured to generate a first voltage to be applied to the chamber, the first voltage corresponding to an RF power;
a voltage source configured to generate a second voltage to be applied to the chamber;
a controller configured to control supply times, frequencies, and voltage values of the RF power and the second voltage; and
a matcher between the RF power source and the chamber,
wherein the RF power source comprises a first source connected to a first electrode at a lower part of the chamber and configured to apply RF power of a first frequency,
the first frequency is higher than a second frequency,
the voltage source is connected to the first electrode and further configured to apply to the chamber the second voltage of the second frequency, and
the matcher is configured to present an impedance match to the RF power source.

17. The plasma control device of claim 16, wherein the controller is further configured to perform a control so that the RF power is applied in an on state when the second voltage is in an on state.

18. The plasma control device of claim 17, wherein the controlling of the RF power and the second voltage by the controller comprises:
a first operation of generating plasma by applying both the RF power and the second voltage to the chamber until a first time is reached;
a second operation of cutting off the RF power after the first time is reached, and continuously applying the second voltage to the chamber until a second time is reached; and
a third operation of cutting off the second voltage after the second time is reached, and maintaining an off state of the RF power and of the second voltage after the second time is reached.

19. The plasma control device of claim 18, wherein the controller is further configured to control a duration of the second operation to be within a range of about 10 μs to about 100 μs, and
during the second operation, negative ions of the plasma formed inside the chamber move toward the wafer, and a plasma potential inside the chamber gradually decreases from a central part of the chamber to the lower part of the chamber.

20. The plasma control device of claim 18, wherein the controller is further configured to perform a control so that the second frequency of the second voltage applied in the first operation is different from the second frequency of the second voltage applied in the second operation.
